(19) United States
(12) Patent Application Publication
(10) Pub. No.: US 2025/0006765 A1
(43) Pub. Date: Jan. 2, 2025

(54) IMAGE SENSOR

(71) Applicant: SAMSUNG ELECTRONICS CO., LTD., Suwon-si (KR)

(72) Inventors: Jehyung RYU, Suwon-si (KR); Hajin Lim, Suwon-si (KR); Taeksoo Jeon, Suwon-si (KR)

(73) Assignee: SAMSUNG ELECTRONICS CO., LTD., Suwon-si (KR)

(21) Appl. No.: 18/758,732

(22) Filed: Jun. 28, 2024

(30) Foreign Application Priority Data
Jun. 29, 2023 (KR) 10-2023-0084509
Sep. 25, 2023 (KR) 10-2023-0128490

(51) Int. Cl. H01L 27/146

(52) U.S. Cl. CPC H01L 27/1463; H01L 27/14636

(57) ABSTRACT

An image sensor is provided. The image sensor includes a semiconductor substrate including a first surface, and a second surface opposite to the first surface, the semiconductor substrate further including a photoelectric conversion region; a transmission gate disposed on the first surface of the semiconductor substrate; a buried insulation layer disposed on the first surface of the semiconductor substrate to cover the transmission gate; and a pixel isolation structure disposed in a pixel isolation trench, the pixel isolation trench extending toward the second surface of the semiconductor substrate from the first surface of the semiconductor substrate and passing through the buried insulation layer, the pixel isolation structure defining a plurality of pixels in the semiconductor substrate, a portion of the pixel isolation structure being covered by the buried insulation layer.

### CROSS-REFERENCE TO RELATED APPLICATION(S)

This application is based on and claims priority under 35 U.S.C. § 119 to Korean Patent Application Nos. 10-2023-0084509, filed on Jun. 29, 2023, and 10-2023-0128490, filed on Sep. 25, 2023, in the Korean Intellectual Property Office, the disclosure of which are herein incorporated by reference in their entireties.

### BACKGROUND

Example embodiments of the disclosure relate to an image sensor, and more particularly, to an image sensor including a deep trench isolation structure.

Image sensors are devices which convert an optical image signal into an electrical signal. An image sensor includes a plurality of pixels, and each of the plurality of pixels includes a photodiode region which receives incident light and converts the received light into an electrical signal and a pixel circuit which outputs a pixel signal by using an electric charge generated by the photodiode region. As the degree of integration of the image sensor increases, the size of each pixel is reduced, and due to this, there is a problem that it is difficult to decrease or prevent a dark current.

### SUMMARY

Example embodiments of the disclosure provide an image sensor which may decrease a dark current and may reduce or prevent an optical crosstalk.

According to an aspect of an example embodiment, an image sensor according includes: a semiconductor substrate including a first surface, and a second surface opposite to the first surface, the semiconductor substrate further including a photoelectric conversion region; a transmission gate disposed on the first surface of the semiconductor substrate; a buried insulation layer disposed on the first surface of the semiconductor substrate to cover the transmission gate; and a pixel isolation structure disposed in a pixel isolation trench, the pixel isolation trench extending toward the second surface of the semiconductor substrate from the first surface of the semiconductor substrate and passing through the buried insulation layer, the pixel isolation structure defining a plurality of pixels in the semiconductor substrate, a portion of the pixel isolation structure being covered by the buried insulation layer.

According to an aspect of an example embodiment, an image sensor includes: a semiconductor substrate including a first surface, and a second surface opposite to the first surface, the semiconductor substrate further including a photoelectric conversion region; a transmission gate disposed on the first surface of the semiconductor substrate; an etch stop layer disposed on the first surface of the semiconductor substrate to cover the transmission gate; and a pixel isolation structure disposed in a pixel isolation trench, the pixel isolation trench extending toward the second surface of the semiconductor substrate from the first surface of the semiconductor substrate, the pixel isolation structure including a conductive layer including a reflective metal material, wherein an end portion of the etch stop layer is disposed on the conductive layer, and the pixel isolation structure and the etch stop layer do not vertically overlap each other.

According to an aspect of an example embodiment, an image sensor includes: a semiconductor substrate including a first surface, and a second surface opposite to the first surface, the semiconductor substrate further including a photoelectric conversion region; a transmission gate disposed on the first surface of the semiconductor substrate; and a pixel isolation structure disposed in a pixel isolation trench, the pixel isolation trench extending up to the second surface of the semiconductor substrate from the first surface of the semiconductor substrate, wherein the pixel isolation structure includes: a conductive layer disposed in the pixel isolation trench, the conductive layer extending in a vertical direction perpendicular to the first surface of the semiconductor substrate; a barrier conductive layer disposed on a sidewall of the conductive layer, in the pixel isolation trench; a pixel isolation insulation layer disposed on the conductive layer and the barrier conductive layer, in the pixel isolation trench; and an insulation liner extending in the vertical direction on an inner wall of the pixel isolation trench, the insulation liner covering a sidewall of the pixel isolation insulation layer and a sidewall of the barrier conductive layer; and an upper surface of the pixel isolation insulation layer is disposed at a level which is higher than the first surface of the semiconductor substrate.

### BRIEF DESCRIPTION OF THE DRAWINGS

Example embodiments will be more clearly understood from the following detailed description taken in conjunction with the accompanying drawings in which:

FIG. 1 is a block diagram illustrating a configuration of an image sensor according to an embodiment;

FIG. 2 is a block diagram illustrating a configuration of an image sensor according to an embodiment;

FIG. 3 is a readout circuit diagram of an image sensor according to example embodiments;

FIG. 4 is a readout diagram illustrating an image sensor according to example embodiments;

FIG. 5 is a cross-sectional view taken along line A1-A1′ of FIG. 4;

FIG. 6 is a plan view at a first vertical level of FIG. 5;

FIG. 7 is a plan view at a second vertical level of FIG. 5;

FIG. 8 is a cross-sectional view illustrating an image sensor according to example embodiments;

FIG. 9 is a plan view at a second vertical level of FIG. 8;

FIG. 10 is a cross-sectional view illustrating an image sensor according to example embodiments;

FIG. 11 is a cross-sectional view illustrating an image sensor according to example embodiments;

FIG. 12 is a plan view at a second vertical level of FIG. 12;

FIG. 13 is a cross-sectional view illustrating an image sensor according to example embodiments;

FIG. 14 is a cross-sectional view illustrating an image sensor according to example embodiments;

FIG. 15 is a cross-sectional view illustrating an image sensor according to example embodiments; and

FIG. 16 is a cross-sectional view illustrating an image sensor according to example embodiments.

### DETAILED DESCRIPTION

Hereinafter, example embodiments will be described in detail with reference to the accompanying drawings.

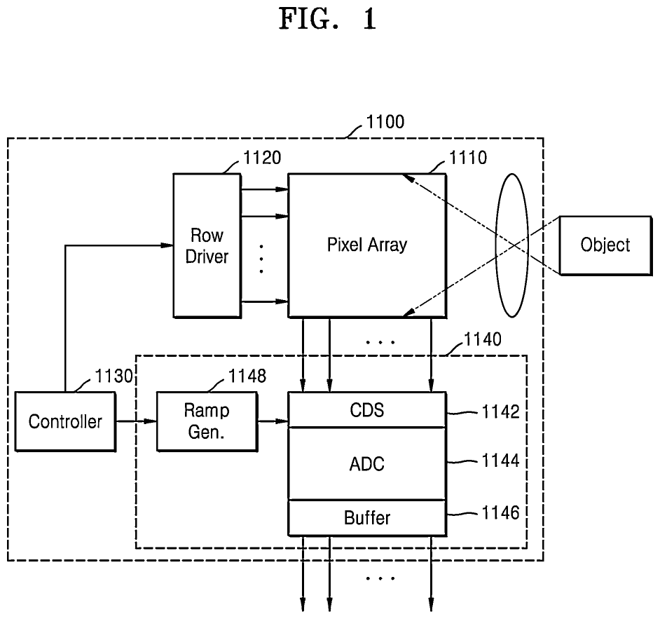

FIG. 1 is a block diagram illustrating a configuration of an image sensor 1100 according to an embodiment.

Referring to FIG. 1, the image sensor 1100 may include a pixel array 1110, a controller 1130, a row driver 1120, and a pixel signal processor 1140.

The pixel array 1110 may include a plurality of unit pixels which are two-dimensionally arranged, and each of the plurality of unit pixels may include an organic photoelectric conversion device. The organic photoelectric conversion device may absorb light to generate an electric charge, and an electrical signal (or an output voltage) based on the generated electric charge may be supplied to the pixel signal processor 1140 through a vertical signal line. The unit pixels included in the pixel array 1110 may supply an output voltage one-by-one at a time by a row unit, and thus, unit pixels included in one row of the pixel array 1110 may be simultaneously activated by a selection signal output from the row driver 1120. Unit pixels included in a selected row may supply an output voltage based on absorbed light to an output line of a corresponding column line.

The controller 1130 may control the row driver 1120 such that the pixel array 1110 absorbs light to accumulate electric charges, or temporarily stores the accumulated electric charges, or outputs an electrical signal based on the stored electrical charges to an outside of the pixel array 1110. Also, the controller 1130 may control the pixel signal processor 1140 to detect the output voltage provided by the pixel array 1110.

The pixel signal processor 1140 may include a correlated double sampler (CDS) 1142, an analog-to-digital converter (ADC) 1144, and a buffer 1146. The CDS 1142 may sample and hold the output voltage provided by the pixel array 1110. The CDS 1142 may sample twice a certain noise level and a level based on a generated output voltage to output a level corresponding to a difference therebetween. Also, the CDS 1142 may receive and compare ramp signals generated by a ramp signal generator 1148 to output a comparison result.

The ADC 1144 may convert an analog signal, corresponding to a level received from the CDS 1142, into a digital signal. The buffer 1146 may latch the digital signal, and the latched signal may be sequentially output to the image sensor 1100 and may be transferred to an image processor (not shown).

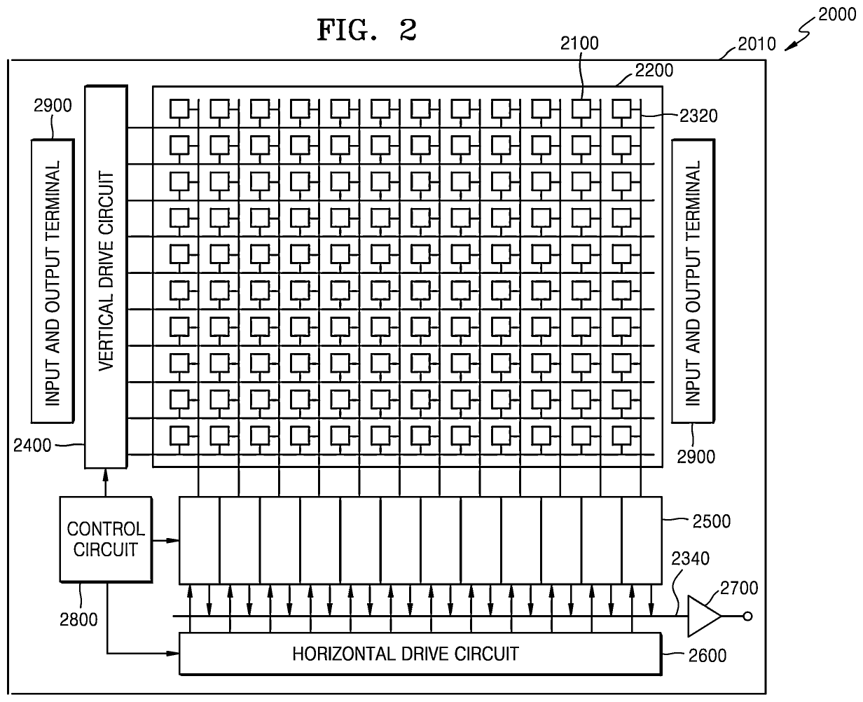

FIG. 2 is a block diagram illustrating a configuration of an image sensor 2000 according to an embodiment.

Referring to FIG. 2, the image sensor 2000 may include a pixel unit 2200 and a peripheral circuit unit. In the pixel unit 2200, a plurality of unit pixels 2100 each including a photoelectric conversion layer may be regularly (e.g., at regular intervals) arranged in a two-dimensional (2D) array structure.

The peripheral circuit unit may be disposed at a periphery of the pixel unit 2200 and may include a vertical driving circuit 2400, a column signal processing circuit 2500, a horizontal driving circuit 2600, an output circuit 2700, a control circuit 2800, and input and output terminal 2900.

The control circuit 2800 may control the vertical driving circuit 2400, the column signal processing circuit 2500, and the horizontal driving circuit 2600. For example, the control circuit 2800 may generate a clock signal or control signals to be used in operations of the vertical driving circuit 2400, the column signal processing circuit 2500, and the horizontal driving circuit 2600, based on a vertical synchronization signal, a horizontal synchronization signal, and a master clock. Also, the control circuit 2800 may input the clock signal or the control signals to the vertical driving circuit 2400, the column signal processing circuit 2500, and the horizontal driving circuit 2600.

The vertical driving circuit 2400 may be configured with, for example, a shift register. The vertical driving circuit 2400 may select a pixel driving wiring and may supply a pulse, which is for driving the plurality of unit pixels 2100, to the selected pixel driving wiring by a row unit. For example, the vertical driving circuit 2400 may sequentially and selectively scan the pulse to each unit pixel 2100 of the pixel unit 2200 in a vertical direction by a row unit. Also, the vertical driving circuit 2400 may apply a pixel signal based on electric charges, generated by the photoelectric conversion layer of each unit pixel 2100, to the column signal processing circuit 2500 through a vertical signal line 2320.

The column signal processing circuit 2500 may be disposed in each column of the plurality of unit pixels 2100 and may perform, for each unit pixel of one row, signal processing such as noise removal on a signal output from each unit pixel 2100. For example, the column signal processing circuit 2500 may perform signal processing such as correlated double sampling (CDS), signal amplification, or analog-to-digital conversion for removing unique noise of the unit pixel 2100. A horizontal selection switch (not shown) may be provided at an output end of the column signal processing circuit 2500.

The horizontal driving circuit 2600 may be configured with, for example, a shift register. The horizontal driving circuit 2600 may sequentially output a horizontal scan pulse to sequentially select each of a plurality of column signal processing circuits 2500 and may output a pixel signal of each column signal processing circuit 2500 to a horizontal signal line 2340.

The output circuit 2700 may process and output signals sequentially supplied from each of the column signal processing circuits 2500 through the horizontal signal line 2340. For example, the output circuit 2700 may perform only buffering, or may perform black level adjustment, column non-uniformity correction, and various digital signal processing. Furthermore, the input and output terminal 2900 may exchange a signal (e.g., transmit and/or receive a signal) with an outside.

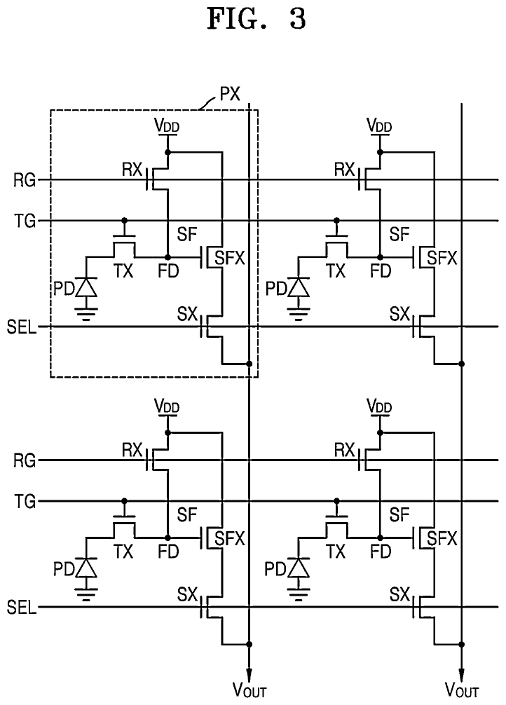

FIG. 3 is a readout circuit diagram of an image sensor according to example embodiments.

Referring to FIG. 3, a plurality of pixels PX may be arranged in a matrix form (e.g., in columns and rows), and each of the plurality of pixels PX may include a transmission transistor TX and logic transistors. Here, the logic transistors may include a reset transistor RX, a selection transistor SX, and a source follower transistor (or a drive transistor) SFX. The reset transistor RX may include a reset gate RG, the selection transistor SX may include a selection gate SEL, the source follower transistor SFX may include a source follower gate SF, and the transmission transistor TX may include a transmission gate TG.

Each of the plurality of pixels PX may further include a photoelectric conversion region PD and a floating diffusion region FD. The photoelectric conversion region PD may generate and accumulate photocharges in proportion to an amount of light incident thereon from an outside and may use a photodiode, a phototransistor, a photo gate, a pinned photodiode (PPD), and/or any combination thereof.

The transmission gate TG may transfer an electric charge, generated by the photoelectric conversion region PD, to the floating diffusion region FD. The floating diffusion region FD may receive, accumulate, and store photoelectric charges generated by the photoelectric conversion region PD. The source follower gate SF of the source follower transistor SFX may be connected with the floating diffusion region FD, and the source follower transistor SFX may be controlled based on an amount of photocharges accumulated in the floating diffusion region FD.

The reset transistor RX may periodically reset photocharges accumulated in the floating diffusion region FD. A drain electrode of the reset transistor RX may be connected with the floating diffusion region FD, and a source electrode of the reset transistor RX may be connected with a source voltage VDD. When the reset transistor RX is turned on, the source voltage VDD connected with the source electrode of the reset transistor RX may be transferred to the floating diffusion region FD. When the reset transistor RX is turned on, electric charges accumulated in the floating diffusion region FD may be discharged, and thus, the floating diffusion region FD may be reset.

The source follower transistor SFX may be connected with a current source (not shown) disposed outside the plurality of pixels PX to function as a source follower buffer amplifier and may amplify an electric potential variation in the floating diffusion region FD to output an amplified value to an output line V_{OUT}.

The selection transistor SX may select the plurality of pixels PX by a column unit, and when the selection transistor SX is turned on, an output voltage generated by the source follower transistor SFX may be transferred to the output line V_{OUT}.

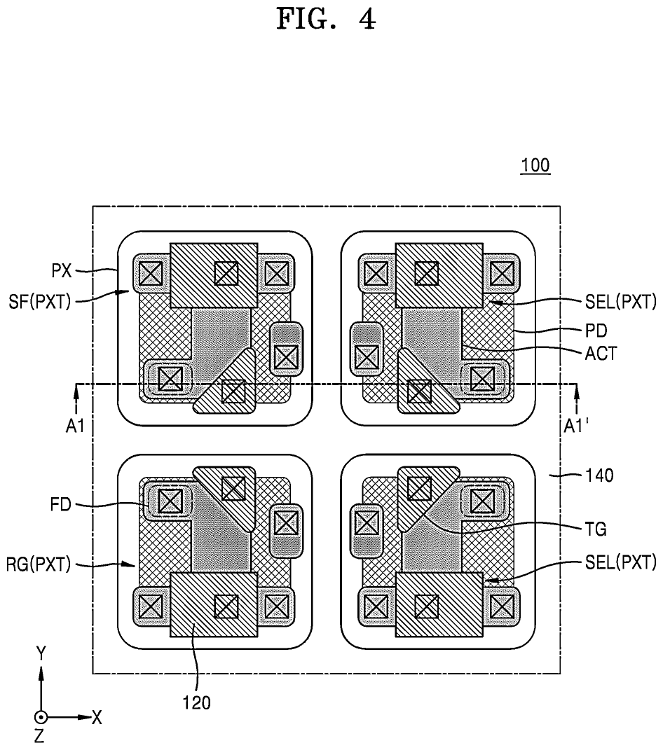

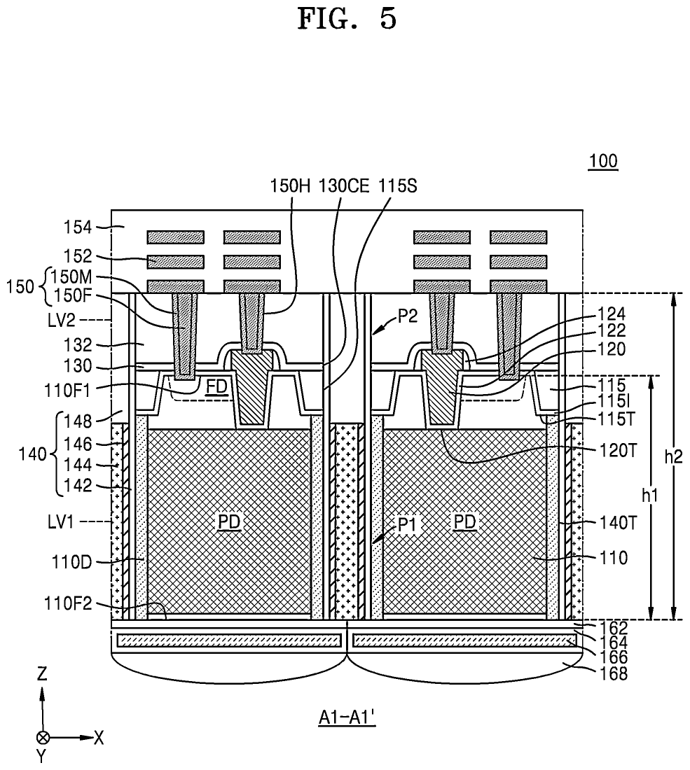

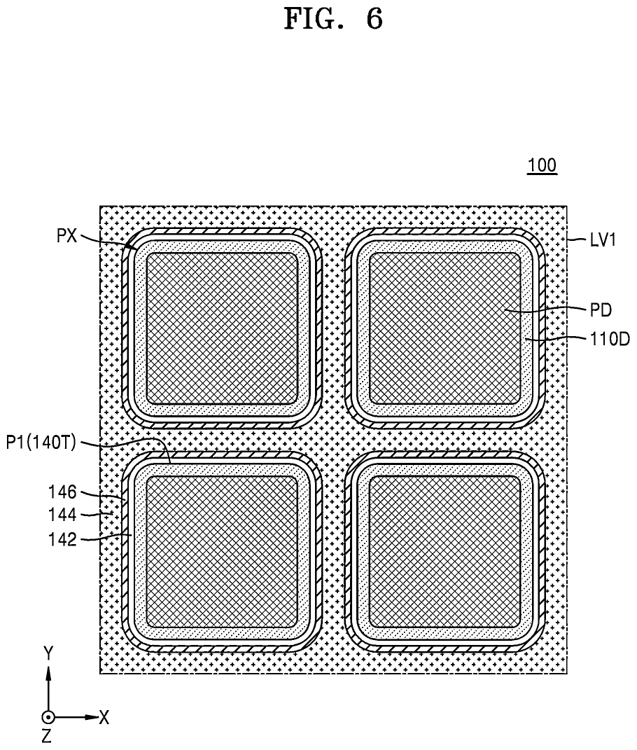

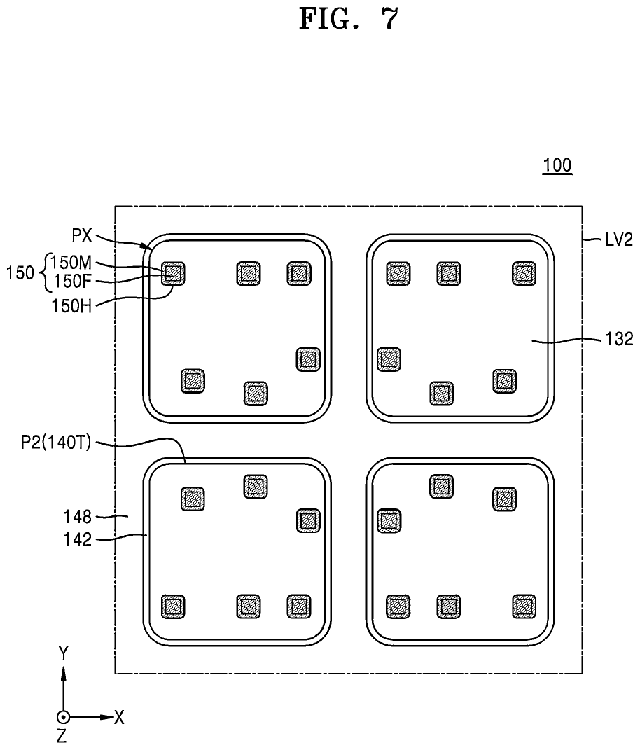

FIG. 4 is a readout diagram illustrating an image sensor 100 according to example embodiments. FIG. 5 is a cross-sectional view taken along line A1-A1′ of FIG. 4. FIG. 6 is a plan view of the image sensor 100 at a first vertical level LV1 of FIG. 5, and FIG. 7 is a plan view of the image sensor 100 at a second vertical level LV2 of FIG. 5.

Referring to FIGS. 4 and 5, the image sensor 100 may include a semiconductor substrate 110 including a plurality of pixels PX.

The semiconductor substrate 110 may include a first surface 110F1 and a second surface 110F2, which are opposite to each other. In example embodiments, the semiconductor substrate 110 may include a P-type semiconductor substrate. For example, the semiconductor substrate 110 may include a P-type silicon substrate. In example embodiments, the semiconductor substrate 110 may include a P-type bulk substrate and a P-type or N-type epitaxial layer grown thereon. In other example embodiments, the semiconductor substrate 110 may include an N-type bulk substrate and a P-type or N-type epitaxial layer grown thereon.

The plurality of pixels PX may be arranged in a matrix form in the semiconductor substrate 110, and a plurality of photoelectric conversion regions PD may be respectively disposed in the plurality of pixels PX. The photoelectric conversion region PD may be a region doped with n-type impurities. For example, the photoelectric conversion region PD may have an impurity concentration difference between an upper portion and a lower portion thereof and may thus have a potential slope. Alternatively, the photoelectric conversion region PD may be formed as a type where a plurality of impurity regions are stacked in a vertical direction. A p-well region (not shown) may be disposed in a partial region adjacent to the first surface 110F1 of the semiconductor substrate 110. The p-well region may be disposed adjacent to the photoelectric conversion region PD and may be a region doped with p-type impurities.

A device isolation layer 115 defining an active region ACT may be formed on the first surface 110F1 of the semiconductor substrate 110. The device isolation layer 115 may be disposed in a device isolation trench 115T, which is formed to have a certain depth in the first surface 110F1 of the semiconductor substrate 110. The device isolation layer 115 may include silicon oxide, silicon nitride, silicon oxynitride, or a combination thereof. An interface insulation layer 115I may be further provided on an inner wall of the device isolation trench 115T and may be conformally disposed between the semiconductor substrate 110 and the device isolation layer 115.

Transistors configuring a pixel circuit PXT may be disposed on the active region ACT. For example, the active region ACT may be a portion of the semiconductor substrate 110 where a transmission gate TG, a source follower gate SF, a selection gate SEL, and a reset gate RG are disposed at an upper portion thereof. A floating diffusion region FD may be disposed in, for example, a portion of the active region ACT (for example, a portion of the active region ACT adjacent to the transmission gate TG).

In example embodiments, the transmission gate TG may configure a transmission transistor TX (see FIG. 3), and the transmission transistor TX may be configured to transfer an electric charge, generated by the photoelectric conversion region PD, to the floating diffusion region FD. The reset gate RG may configure a reset transistor RX (see FIG. 3), and the reset transistor RX may be configured to periodically reset an electric charge stored in the floating diffusion region FD. The source follower gate SF may configure a source follower transistor SFX (see FIG. 3), and the source follower transistor SFX may function as a source follower buffer amplifier and may be configured to buffer a signal based on an electric charge charged into the floating diffusion region FD. The selection gate SEL may configure a selection transistor SX (see FIG. 3), and the selection transistor SX may perform a switching and addressing function for selecting a pixel PX.

The transmission gate TG, the reset gate RG, the source follower gate SF, and the selection gate SEL each include a gate electrode 120. For example, the gate electrode 120 may be disposed in a buried gate trench 120T, or may be disposed on the first surface 110F1 of the semiconductor substrate 110.

In example embodiments, the gate electrode 120 may include at least one of doped polysilicon, metal, metal silicide, metal nitride, or a metal-containing film. A gate insulation layer 122 may be disposed between the gate electrode 120 and the first surface 110F1 of the semiconductor substrate 110 and on an inner wall of the buried gate trench 120T. A gate spacer 124 may be disposed on a sidewall of the gate electrode 120.

The floating diffusion region FD may be disposed in the semiconductor substrate 110, adjacent to or on one side of the gate electrode 120 (for example, the transmission gate TG). In example embodiments, the floating diffusion region FD may be a region doped with first impurities, and for example, the first impurities may be n-type impurities. In some example embodiments, the first impurities may include phosphorus or arsenic.

An etch stop layer 130 covering the gate electrode 120 may be formed on the first surface 110F1 of the semiconductor substrate 110. The etch stop layer 130 may conformally cover an upper surface of the gate electrode 120 and an upper surface and a sidewall of the gate spacer 124, and moreover, the etch stop layer 130 may be disposed on an upper surface of the device isolation layer 115. The etch stop layer 130 may include silicon nitride or silicon oxynitride and may be configured as a single layer or a double layer.

A buried insulation layer 132 may be disposed on the etch stop layer 130. The buried insulation layer 132 may be disposed on the etch stop layer 130 to have a sufficiently large height and fully cover the gate electrode 120, and an upper surface of the buried insulation layer 132 may have a flat profile. In example embodiments, the buried insulation layer 132 may include at least one of silicon oxide, silicon oxynitride, silicon nitride, and a low-k dielectric material.

A pixel isolation structure 140 may be disposed in at least a portion of the semiconductor substrate 110, and the plurality of pixels PX may be defined by the pixel isolation structure 140. The pixel isolation structure 140 may be disposed between one of a plurality of photoelectric conversion regions PD and a photoelectric conversion region PD adjacent thereto. One photoelectric conversion region PD and the other photoelectric conversion region PD adjacent thereto may be physically and electrically isolated by the pixel isolation structure 140. The pixel isolation structure 140 may be disposed between two adjacent photoelectric conversion regions PD of the plurality of photoelectric conversion regions PD arranged in a matrix form and may have a grid or mesh shape in a plan view.

The pixel isolation structure 140 may be formed in a pixel isolation trench 140T. The pixel isolation trench 140T may pass through the semiconductor substrate 110 up to the second surface 110F2 of the semiconductor substrate 110 from the first surface 110F1 of the semiconductor substrate 110, extend in a vertical direction Z through the first surface 110F1 of the semiconductor substrate 110, and pass through the buried insulation layer 132.

The pixel isolation trench 140T may include a first portion P1, which passes through the semiconductor substrate 110 up to the second surface 110F2 of the semiconductor substrate 110 from the first surface 110F1 of the semiconductor substrate 110, and a second portion P2, which passes through the buried insulation layer 132 and is disposed at a vertical level (e.g., along a Z direction) which is higher than the first portion P1. Here, being disposed at a high vertical level may denote being disposed farther away from the second surface 110F2 of the semiconductor substrate 110. For example, the second portion P2 of the pixel isolation trench 140T may be disposed at a vertical level which is higher than the first surface 110F1 of the semiconductor substrate 110, and the first portion P1 of the pixel isolation trench 140T may be disposed at a vertical level which is equal to or lower than the first surface 110F1 of the semiconductor substrate 110 and higher than the second surface 110F2 of the semiconductor substrate 110.

In example embodiments, the gate electrode 120 may be formed on the first surface 110F1 of the semiconductor substrate 110 and the etch stop layer 130 and the buried insulation layer 132 each covering the upper surface of the gate electrode 120 may be formed, and then, the pixel isolation trench 140T may be formed by removing a portion of the buried insulation layer 132 and a portion of the semiconductor substrate 110. Therefore, the first portion P1 and the second portion P2 of the pixel isolation trench 140T may include sidewalls which are continuously connected and aligned with each other.

In example embodiments, the pixel isolation structure 140 may include an insulation liner 142, a conductive layer 144, a barrier conductive layer 146, and a pixel isolation insulation layer 148.

The insulation liner 142 may be disposed on an inner wall of the pixel isolation trench 140T. For example, the insulation liner 142 may be disposed all over an inner wall of each of the first portion P1 and the second portion P2 of the pixel isolation trench 140T. The insulation liner 142 may extend from the second surface 110F2 of the semiconductor substrate 110 up to the first surface 110F1 of the semiconductor substrate 110 and further extend up to an upper side of a sidewall of the buried insulation layer 132 through the first surface 110F1 of the semiconductor substrate 110. The insulation liner 142 may extend such that a portion of the insulation liner 142 is disposed at the same vertical level as the upper surface of the buried insulation layer 132. In some example embodiments, the insulation liner 142 may include an insulating material such as silicon oxide, silicon nitride, or silicon oxynitride. In example embodiments, the insulation liner 142 may include metal oxide such as hafnium oxide, aluminum oxide, or tantalum oxide.

The conductive layer 144 may be disposed in the first portion P1 of the pixel isolation trench 140T and may extend in the vertical direction Z. In example embodiments, the conductive layer 144 may include a reflective metal material. The conductive layer 144 may include at least one of aluminum (Al), copper (Cu), silver (Ag), cobalt (Co), tungsten (W), platinum (Pt), gold (Au), chromium (Cr), titanium (Ti), nickel (Ni), molybdenum (Mo), iron (Fe), magnesium (Mg), iridium (Ir), palladium (Pd), and ruthenium (Ru). However, a material included in the conductive layer 144 is not limited to the kinds of the materials described above, and the conductive layer 144 may include another metal material which is not described herein.

In example embodiments, the conductive layer 144 may include an upper surface disposed at a level which is lower than a bottom surface of the device isolation layer 115. The conductive layer 144 may include the reflective metal material and may thus reflect light, which is incident in a slope angle toward the pixel isolation structure 140, to the inside of the pixel PX.

The barrier conductive layer 146 may be disposed in the first portion P1 of the pixel isolation trench 140T and may extend in the vertical direction Z. The barrier conductive layer 146 may be disposed between the conductive layer 144 and the insulation liner 142, and thus, the conductive layer 144 may not directly contact the insulation liner 142. In example embodiments, the barrier conductive layer 146 may include at least one of titanium, titanium nitride, titanium aluminum, titanium silicon, cobalt, and cobalt silicon.

The pixel isolation insulation layer 148 may be disposed on the conductive layer 144 and the barrier conductive layer 146, in the pixel isolation trench 140T. For example, the pixel isolation insulation layer 148 may be disposed in the second portion P2 of the pixel isolation trench 140T and in an upper portion of the first portion P1 of the pixel isolation trench 140T. Both sidewalls of the pixel isolation insulation layer 148 may be covered by the insulation liner 142.

In example embodiments, the pixel isolation insulation layer 148 may include an upper surface disposed at the same level as the upper surface of the buried insulation layer 132, and the insulation liner 142 may be disposed between the pixel isolation insulation layer 148 and the buried insulation layer 132. A bottom surface of the pixel isolation insulation layer 148 may be disposed at a level which is lower than the bottom surface of the device isolation layer 115. In example embodiments, the pixel isolation insulation layer 148 may include at least one of silicon oxide, silicon oxynitride, silicon nitride, and a low-k dielectric material.

In example embodiments, because the pixel isolation structure 140 is disposed in the first portion P1 and the second portion P2 of the pixel isolation trench 140T, a lower side of the pixel isolation structure 140 may be disposed to pass through an inner portion of the semiconductor substrate 110, and an upper side of the pixel isolation structure 140 may be disposed to pass through the buried insulation layer 132.

For example, FIG. 6 illustrates a plan view of the image sensor 100 at the first vertical level LV1, which is lower than the first surface 110F1 of the semiconductor substrate 110 and higher than the second surface 110F2 of the semiconductor substrate 110. As illustrated in FIG. 6, a lower side of the pixel isolation structure 140 (for example, the insulation liner 142, the conductive layer 144, and the barrier conductive layer 146 of the pixel isolation structure 140) disposed in the first portion P1 of the pixel isolation trench 140T may be disposed to surround the plurality of pixels PX of the semiconductor substrate 110 in a plan view. Also, FIG. 7 illustrates a plan view of the image sensor 100 at the second vertical level LV2, which is higher than the first surface 110F1 of the semiconductor substrate 110. As illustrated in FIG. 7, an upper side of the pixel isolation structure 140 (for example, the insulation liner 142 and the pixel isolation insulation layer 148 of the pixel isolation structure 140) disposed in the second portion P2 of the pixel isolation trench 140T may be disposed to surround the buried insulation layer 132 at a position corresponding to each of the plurality of pixels PX in a plan view.

As illustrated in FIG. 5, an upper side of a sidewall of the pixel isolation structure 140 may contact a sidewall of the buried insulation layer 132 and may be covered by the buried insulation layer 132. A portion of the sidewall of the pixel isolation structure 140 may contact the device isolation layer 115 and the etch stop layer 130. In example embodiments, the etch stop layer 130 may include an end portion 130CE, which extends on the upper surface of the semiconductor substrate 110 and is disposed at a point contacting the second portion P2 of the pixel isolation trench 140T. For example, the insulation liner 142 may be disposed to contact a sidewall 115S of the device isolation layer 115 and contact the end portion 130CE of the etch stop layer 130.

Also, an upper surface of the pixel isolation structure 140 may be disposed at a level which is higher than the first surface 110F1 of the semiconductor substrate 110 and may be disposed at the same level as the upper surface of the buried insulation layer 132. The sidewall of the pixel isolation structure 140 may contact the end portion 130CE of the device isolation layer 130, and the pixel isolation structure 140 may be disposed at a position which does not overlap the device isolation layer 130 in a horizontal direction (e.g., an X direction).

In example embodiments, because the insulation liner 142 is disposed in the first portion P1 and the second portion P2 of the pixel isolation trench 140T, a portion of the insulation liner 142 (for example, a portion of the insulation liner 142 disposed in the second portion P2 of the pixel isolation trench 140T) may be disposed between the buried insulation layer 132 and the pixel isolation insulation layer 148, another portion of the insulation liner 142 (for example, another portion of the insulation liner 142 disposed in the second portion P2 of the pixel isolation trench 140T) may be disposed between the device isolation layer 115 and the pixel isolation insulation layer 148, another portion of the insulation liner 142 (for example, a portion of the insulation liner 142 disposed in the first portion P1 of the pixel isolation trench 140T) may be disposed between the device isolation layer 115 and the pixel isolation insulation layer 148, and another portion of the insulation liner 142 (for example, a portion of the insulation liner 142 disposed in the first portion P1 of the pixel isolation trench 140T) may be disposed between the semiconductor substrate 110 and the barrier conductive layer 144.

In example embodiments, the semiconductor substrate 110 may have a first height h1 in the vertical direction Z. The first height h1 may correspond to a distance up to the second surface 110F2 of the semiconductor substrate 110 from the first surface 110F1 of the semiconductor substrate 110 in the vertical direction Z. The pixel isolation structure 140 may have a second height h2, which is greater than the first height h1 in the vertical direction Z. In some example embodiments, the second height h2 may be about 105% to about 200% of the first height h1, and a ratio of the second height h2 to the first height h1 may be changed based on a dimension of the pixel PX and a layout of the pixel PX.

A barrier impurity region 110D may be disposed in an inner region of the semiconductor substrate 110 disposed adjacent to the pixel isolation trench 140T. The barrier impurity region 110D may be surrounded by the pixel isolation structure 140, in each pixel PX, in a plan view. The barrier impurity region 110D may be a region which is doped with p-type impurities disposed in the semiconductor substrate 110, and the p-type impurities may include boron (B).

A contact 150 may be disposed in a contact hole 150H passing through the buried insulation layer 132 and may be electrically connected with the semiconductor substrate 110 and the gate electrode 120. The contact 150 may include a barrier layer 150M and a buried conductive layer 150F, the barrier layer 150M may be disposed on an inner wall of the contact hole 150H, and the buried conductive layer 150F may fill an inner portion of the contact hole 150H. For example, the barrier layer 150M may be disposed on a sidewall and a bottom surface of the buried conductive layer 150F.

In example embodiments, the buried conductive layer 150F may include at least one of impurity-doped or undoped polysilicon, metal, metal silicide, metal nitride, or a metal-containing layer, and for example, may include tungsten, aluminum, copper, tungsten silicide, titanium silicide, tungsten nitride, titanium nitride, or doped polysilicon. The barrier layer 150M may include titanium nitride, tungsten nitride, tungsten silicide, or titanium silicide.

A wiring layer 152 electrically connected with the contact 150 may be disposed on the buried insulation layer 132, and an interlayer insulation layer 154 covering the wiring layer 152 may be disposed on the buried insulation layer 132.

A backside insulation layer 162 may be disposed on the second surface 110F2 of the semiconductor substrate 110. In example embodiments, the backside insulation liner 162 may include metal oxide such as hafnium oxide, aluminum oxide, or tantalum oxide. In example embodiments, the backside insulation layer 162 may include an insulating material such as silicon oxide, silicon nitride, silicon oxynitride, or a low-k dielectric material.

A passivation layer 164 may be disposed on the backside insulation layer 162, and a color filter 166 and a micro-lens 168 may be disposed on the passivation layer 164.

Generally, a pixel isolation structure may be formed by using polysilicon in a pixel isolation trench, and a negative bias may be applied to the pixel isolation structure, thereby preventing the occurrence of a dark current. However, as a pixel size is miniaturized, there may be a problem that an optical crosstalk occurs where light passes through the pixel isolation structure and is transmitted to or incident on an adjacent pixel.

According to example embodiments, the pixel isolation structure 140 may be disposed to pass through the buried insulation layer 132 and extend in the vertical direction Z, and the pixel isolation structure 140 includes the conductive layer 144 including a reflective metal material, thereby decreasing or preventing an optical crosstalk which may otherwise occur when light is transmitted to or incident on an adjacent pixel.

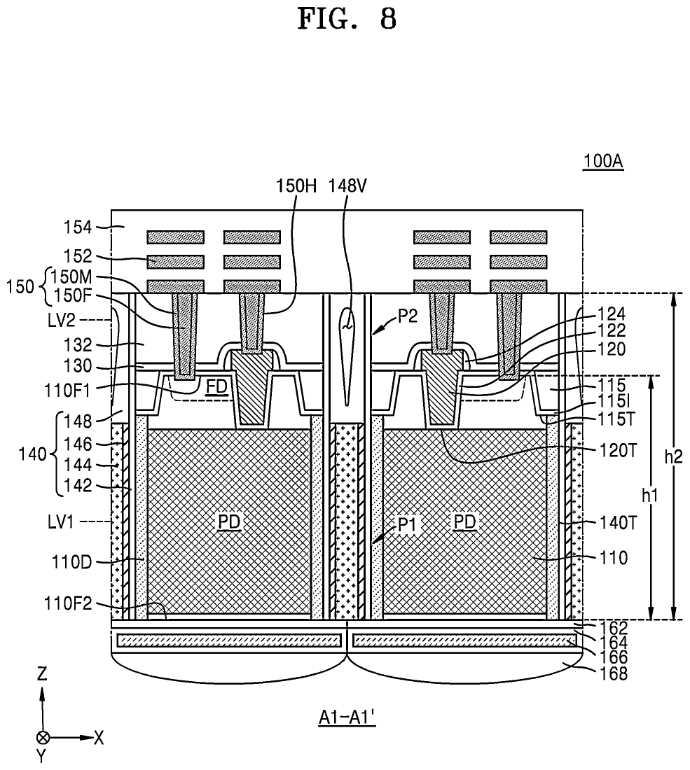

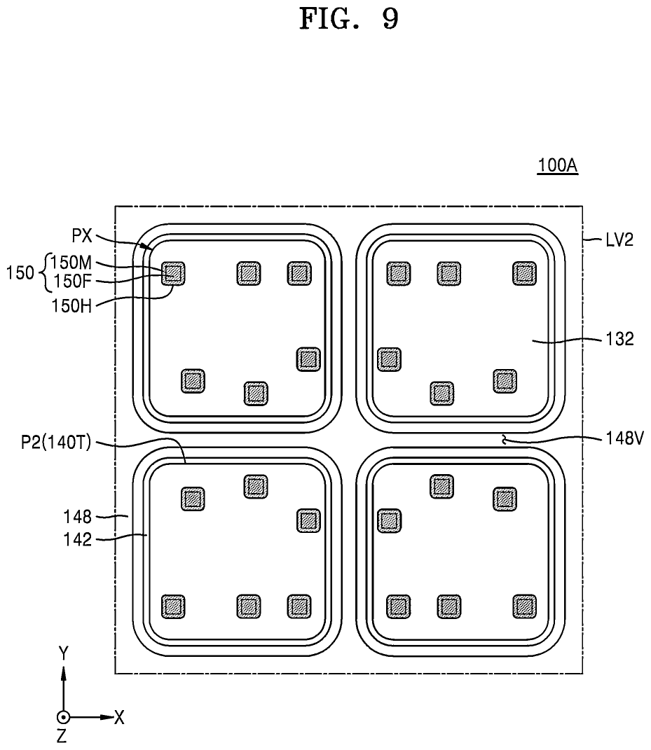

FIG. 8 is a cross-sectional view illustrating an image sensor 100A according to example embodiments. FIG. 9 is a plan view of the image sensor 100A at a second vertical level LV2 of FIG. 8. In FIGS. 8 and 9, the same reference numerals as FIGS. 1 to 7 refer to like elements.

Referring to FIGS. 8 and 9, a pixel isolation insulation layer 148 of a pixel isolation structure 140 may include a void 148V. The void 148V may denote an air space where an insulating material layer configuring the pixel isolation insulation layer 148 is not formed and which is empty.

In example embodiments, the void 148V may extend by a relatively large height in a vertical direction Z up to a vertical level, which is higher than a first surface 110F1 of a semiconductor substrate 110, from a vertical level which is lower than the first surface 110F1 of the semiconductor substrate 110. As illustrated in FIG. 8, the void 148V may be disposed at a level which is lower than an upper surface of a buried insulation layer 132 and may not be exposed to an outside of the pixel isolation structure 140. In other example embodiments, the void 148V may be disposed to extend up to the same level as the upper surface of the buried insulation layer 132.

In example embodiments, the pixel isolation insulation layer 148 may include a material where step coverage is not good. In a process of forming the pixel isolation insulation layer 148 in a second portion P2 of a pixel isolation trench 140T, the pixel isolation insulation layer 148 may not completely fill the second portion P2 of the pixel isolation trench 140T, and thus, the void 148V may remain in the pixel isolation insulation layer 148. The void 148V may include an air space, and the air space may have a dielectric constant which is relatively low. Because the void 148V is included in the pixel isolation insulation layer 148, a conversion gain characteristic of the image sensor 100A may be enhanced.

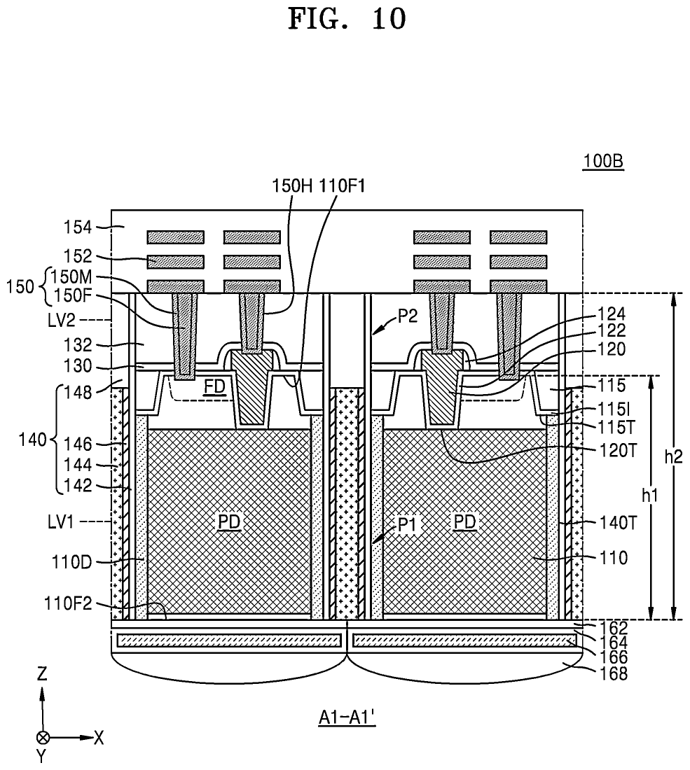

FIG. 10 is a cross-sectional view illustrating an image sensor 100B according to example embodiments. In FIG. 10, the same reference numerals as FIGS. 1 to 9 refer to like elements.

Referring to FIG. 10, upper surfaces of a conductive layer 144 and a barrier conductive layer 146 of a pixel isolation structure 140 may be disposed at a level which is higher than a bottom surface of a device isolation layer 115 and may be disposed at a level which is lower than an upper surface of the device isolation layer 115. A pixel isolation insulation layer 148 of the pixel isolation structure 140 may be formed on the conductive layer 144 and the barrier conductive layer 146, and a bottom surface of the pixel isolation insulation layer 148 may be disposed at a level which is lower than the upper surface of the device isolation layer 115, or may be disposed at a level which is lower than a first surface 110F1 of a semiconductor substrate 110.

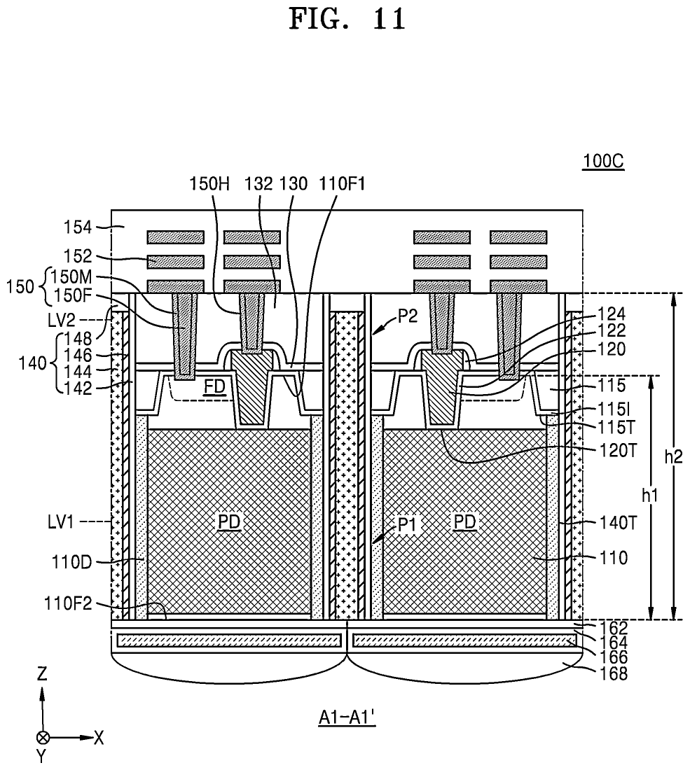

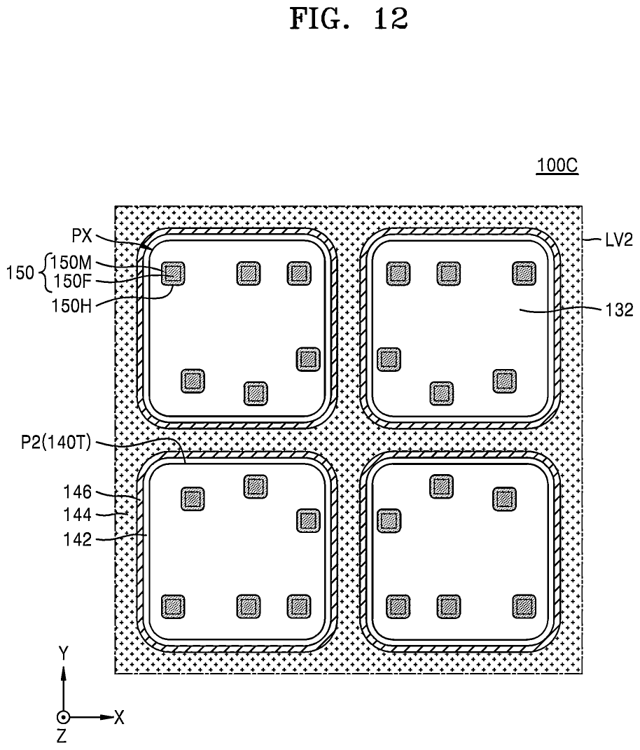

FIG. 11 is a cross-sectional view illustrating an image sensor 100C according to example embodiments. FIG. 12 is a plan view at a second vertical level LV2 of FIG. 11. In FIGS. 11 and 12, the same reference numerals as FIGS. 1 to 10 refer to like elements.

Referring to FIGS. 11 and 12, upper surfaces of a conductive layer 144 and a barrier conductive layer 146 of a pixel isolation structure 140 may be disposed at a level which is higher than an upper surface of a device isolation layer 115 and may be disposed at a level which is lower than an upper surface of a buried insulation layer 132. For example, the conductive layer 144 and the barrier conductive layer 146 may be disposed in a portion or an entire portion of a first portion P1 and/or a second portion P2 of a pixel isolation trench 140T. A portion of the barrier conductive layer 146 and a portion of an insulation liner 142 may be disposed between the conductive layer 144 and the buried insulation layer 132 at a vertical level which is higher than a first surface 110F1 of a semiconductor substrate 110.

For example, as illustrated in FIG. 12 illustrating the plan view at the second vertical level LV2, which is higher than the first surface 110F1 of the semiconductor substrate 110, an upper side of the pixel isolation structure 140 (for example, the insulation liner 142, the conductive layer 144, and the barrier conductive layer 146 of the pixel isolation structure 140) disposed in the second portion P2 of the pixel isolation trench 140T may be disposed to surround the buried insulation layer 132 at a position corresponding to each pixel PX, in a plan view.

In some example embodiments, the pixel isolation insulation layer 148 may be omitted, and the conductive layer 144 and the barrier conductive layer 146 may be disposed within a total height (e.g., a total height of the first portion P1 and the second portion P2) of the pixel isolation trench 140T. In this case, upper surfaces of the conductive layer 144 and the barrier conductive layer 146 may be disposed at the same level as the upper surface of the buried insulation layer 132.

According to example embodiments, the conductive layer 144 including a reflective metal material may extend in the vertical direction Z on the first surface 110F1 of the semiconductor substrate 110, and thus, the pixel isolation structure 140 may reflect light which is incident at a slope angle from one pixel PX toward an adjacent pixel PX, thereby decreasing or preventing an optical crosstalk of the image sensor 100C.

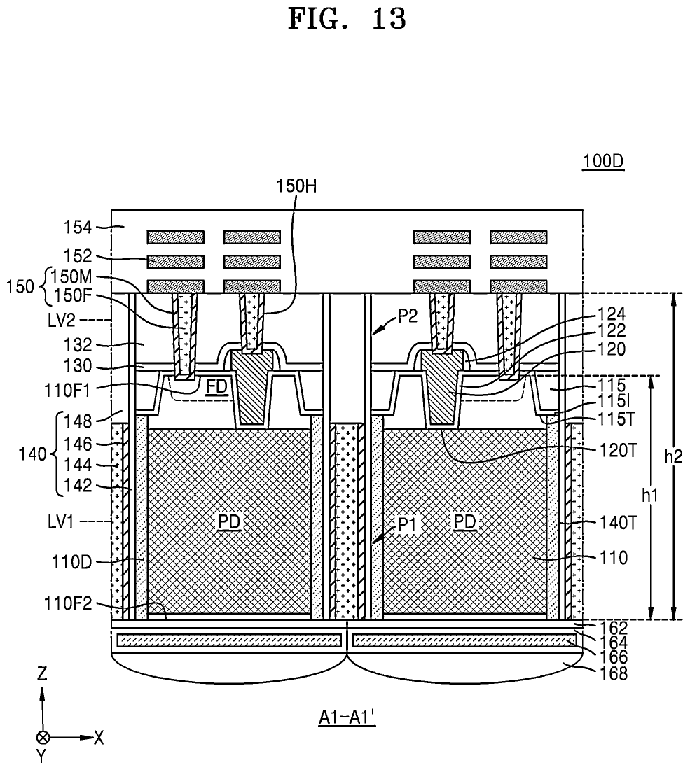

FIG. 13 is a cross-sectional view illustrating an image sensor 100D according to example embodiments. In FIG. 13, the same reference numerals as FIGS. 1 to 12 refer to like elements.

Referring to FIG. 13, a contact 150 may be disposed in a contact hole 150H passing through the buried insulation layer 132 and may be electrically connected with a semiconductor substrate 110 and a gate electrode 120. The contact 150 may include a barrier layer 150M and a buried conductive layer 150F. The barrier layer 150M may include the same material as a material of the barrier conductive layer 146 of the pixel isolation structure 140, and the buried conductive layer 150F may include the same material as a material of the conductive layer 144 of the pixel isolation structure 140.

In example embodiments, the buried conductive layer 150F and the conductive layer 144 may include a reflective metal material. For example, the buried conductive layer 150F may include at least one of Al, Cu, Ag, Co, W, Pt, Au, Cr, Ti, Ni, Mo, Fe, Mg, Ir, Pd, and Ru. In example embodiments, the barrier layer 150M and the barrier conductive layer 146 may include at least one of titanium, titanium nitride, titanium aluminum, titanium silicon, cobalt, and cobalt silicon.

In example embodiments, a gate electrode 120 may be formed on a semiconductor substrate 110 and the buried insulation layer 132 covering the gate electrode 120 may be formed. Subsequently, the contact hole 150H passing through the buried insulation layer 132 and the pixel isolation trench 140T passing through the buried insulation layer 132 and the semiconductor substrate 110 may be formed. Subsequently, a process of forming the barrier layer 150M in the contact hole 150H and a process of forming the barrier conductive layer 146 in the pixel isolation trench 140T may be performed at the same process step, and a process of forming the buried conductive layer 150F in the contact hole 150H and a process of forming the conductive layer 144 in the pixel isolation trench 140T may be performed by the same process at the same process step.

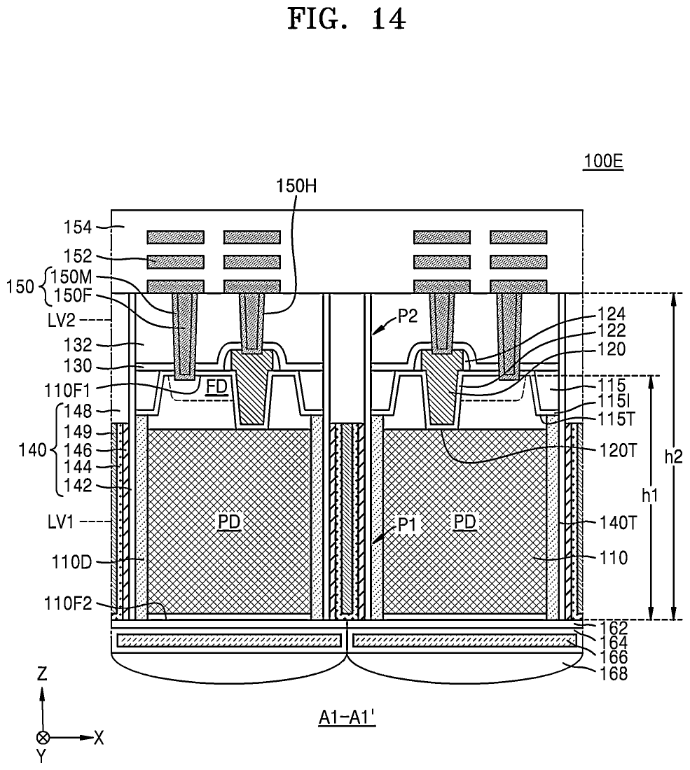

FIG. 14 is a cross-sectional view illustrating an image sensor 100E according to example embodiments. In FIG. 14, the same reference numerals as FIGS. 1 to 13 refer to like elements.

Referring to FIG. 14, a pixel isolation structure 140 may further include a buried conductive layer 149 which is disposed on a conductive layer 144. For example, the conductive layer 144 may be formed to have a relatively thin thickness which does not completely fill an inner portion of the pixel isolation trench 140T, and the buried conductive layer 149 may be formed on the conductive layer 144. In example embodiments, the conductive layer 144 may include a reflective metal material, and the buried conductive layer 149 may include silicon germanium (SiGe), polysilicon, metal, metal nitride, or metal silicide.

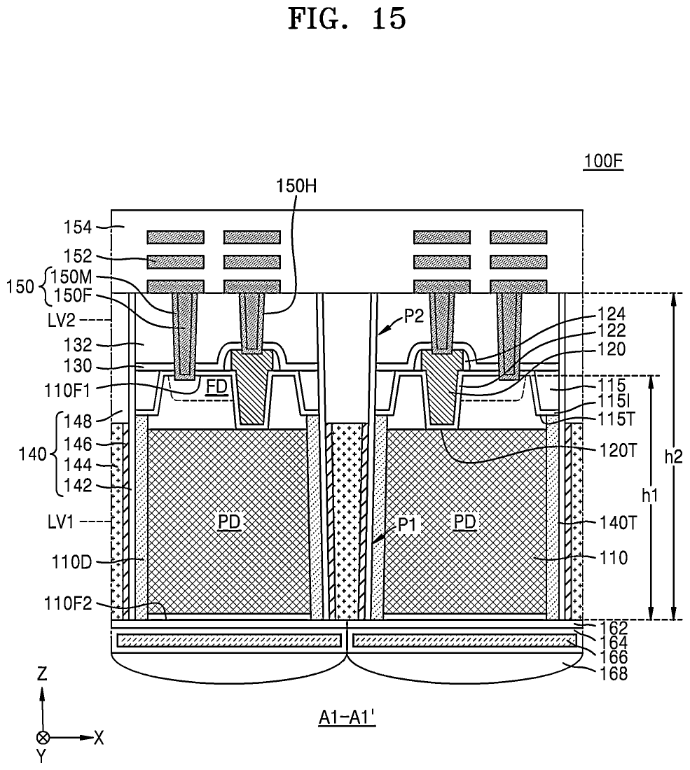

FIG. 15 is a cross-sectional view illustrating an image sensor 100F according to example embodiments. In FIG. 15, the same reference numerals as FIGS. 1 to 14 refer to like elements.

Referring to FIG. 15, a pixel isolation trench 140T may include an inclined sidewall such that a width of a second portion P2 of the pixel isolation trench 140T in a horizontal direction (for example, an X direction or a Y direction) is greater than a width of a first portion P1 of the pixel isolation trench 140T in the horizontal direction, and a horizontal-direction width of the pixel isolation trench 140T at the same level as an upper surface of the buried insulation layer 132 is greater than a horizontal-direction width of the pixel isolation trench 140T at the same level as a second surface 110F2 of a semiconductor substrate 110.

In the embodiments described above with reference to FIGS. 4 to 15, it is illustrated that one pixel PX may be disposed apart from an adjacent pixel PX, and each of a plurality of pixels PX is surrounded by a pixel isolation structure 140 in a plan view. However, in other example embodiments, the pixel isolation structure 140 may not be disposed in at least a partial region between at least one pixel PX of the plurality of pixels PX and an adjacent pixel PX. For example, in a structure where two pixels PX share a floating diffusion region FD, an isolation region or a cut region of the pixel isolation structure 140 may be disposed between two adjacent pixels PX. Alternatively, in a structure where four pixels PX share the floating diffusion region FD, the isolation region or the cut region of the pixel isolation structure 140 may be disposed between four adjacent pixels PX which are arranged in a matrix form.

In the embodiments described above with reference to FIGS. 4 to 15, it is illustrated that at least two gate electrodes 120 are apart from each other on a first surface 110F1 of a semiconductor substrate 110, in one pixel PX. However, in other example embodiments, only a transmission gate TG may be disposed on the first surface 110F1 of the semiconductor substrate 110, the gate electrode 120 (for example, a selection gate SEL, a reset gate RG, and a source follower gate RG) each configuring a pixel circuit PXT may be disposed on an additional semiconductor substrate, the semiconductor substrate 110 may be bonded to the additional semiconductor substrate, and the semiconductor substrate 110 may be electrically connected with the additional semiconductor substrate by a bonding pad and/or a through via between the semiconductor substrate 110 and the additional semiconductor substrate.

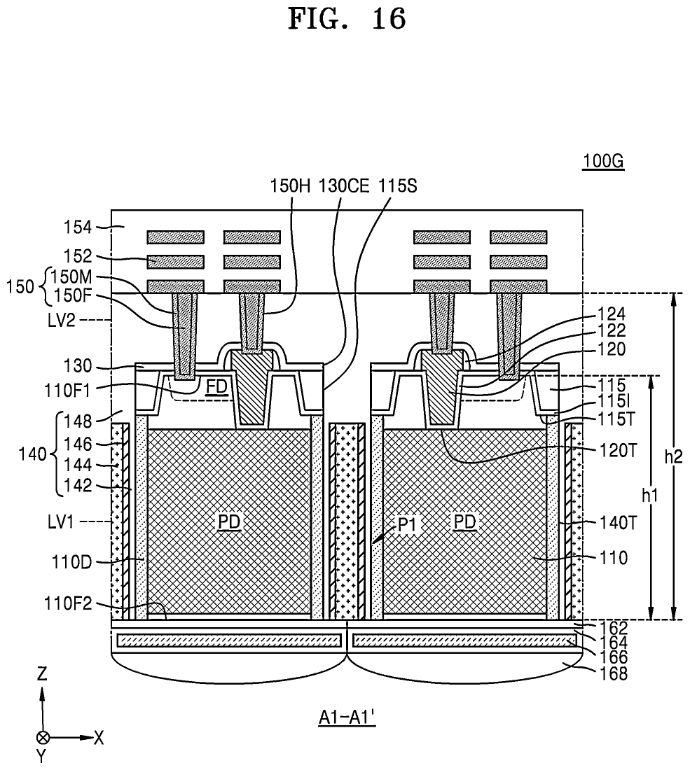

FIG. 16 is a cross-sectional view illustrating an image sensor 100G according to example embodiments.

Referring to FIG. 16, in the image sensor 100G, a buried insulation layer 132, an insulation liner 142, and a pixel isolation insulation layer 148 may include the same material, and thus, a boundary between the buried insulation layer 132 and the insulation liner 142 and a boundary between the insulation liner 142 and the pixel isolation insulation layer 148 may not be clearly identified. In example embodiments, an etch stop layer 130 may include an end portion 130CE, which extends on an upper surface of a semiconductor substrate 110 and is disposed at a point contacting a second portion P2 of a pixel isolation trench 140T. The end portion 130CE of the etch stop layer 130 may extend in a first horizontal direction X and a second horizontal direction Y to correspond to a planar shape of the pixel isolation trench 140T.

The end portion 130CE of the etch stop layer 130 may be aligned with a sidewall of the device isolation layer 115. For example, the sidewall of the device isolation layer 115 may denote a surface of the device isolation layer 115 connected with the pixel isolation trench 140T, and the end portion 130CE of the etch stop layer 130 may be aligned with and disposed at the sidewall of the device isolation layer 115 in a vertical direction Z.

In example embodiments, the buried insulation layer 132, the insulation liner 142, and the pixel isolation insulation layer 148 may include an insulating material such as silicon oxide, and in this case, spaces on upper surfaces of a conductive layer 144 and a barrier conductive layer 146 each disposed at a first portion P1 of the pixel isolation trench 140T may be filled with an insulating material such as silicon oxide.

In example embodiments, a portion of the etch stop layer 130 may be removed and the end portion 130CE of the etch stop layer 130 may be formed in a process of forming the pixel isolation trench 140T, and thus, the conductive layer 144 and the barrier conductive layer 146 may be disposed not to vertically overlap the etch stop layer 130.

According to the embodiments described above, an image sensor may include a pixel isolation structure which extends up to a second surface of a semiconductor substrate from a first surface of the semiconductor substrate and passes through a buried insulation layer, and the pixel isolation structure may include a conductive layer including a reflective metal material. The conductive layer may reflect light, which is incident toward the pixel isolation structure, to the inside of a pixel. Thus, even when a pixel size may be reduced, an optical crosstalk of the image sensor may be decreased or prevented.

Hereinabove, example embodiments have been described in the drawings and the specification. Embodiments have been described by using the terms described herein, but this has been merely used for describing the inventive concept and has not been used for limiting a meaning or limiting the scope of the inventive concept defined in the following claims and their equivalents. Therefore, it would be understood by those of ordinary skill in the art that various modifications and other equivalent embodiments may be implemented from the inventive concept. Accordingly, the spirit and scope of the inventive concept may be defined based on the spirit and scope of the following claims and their equivalents.

While the inventive concept has been particularly shown and described with reference to example embodiments thereof, it will be understood that various changes in form and details may be made therein without departing from the spirit and scope of the following claims and their equivalents.

What is claimed is:

1. An image sensor comprising:
a semiconductor substrate including a first surface, and a second surface opposite to the first surface, the semiconductor substrate further including a photoelectric conversion region;
a transmission gate disposed on the first surface of the semiconductor substrate;
a buried insulation layer disposed on the first surface of the semiconductor substrate to cover the transmission gate; and
a pixel isolation structure disposed in a pixel isolation trench, the pixel isolation trench extending toward the second surface of the semiconductor substrate from the first surface of the semiconductor substrate and passing through the buried insulation layer, the pixel isolation structure defining a plurality of pixels in the semiconductor substrate, a portion of the pixel isolation structure being covered by the buried insulation layer.

2. The image sensor of claim 1, wherein the pixel isolation structure comprises:
an insulation liner disposed on an inner wall of the pixel isolation trench;
a conductive layer disposed in the pixel isolation trench, on the insulation liner;
a pixel isolation insulation layer disposed on the inner wall of the pixel isolation trench and disposed on the conductive layer; and
a barrier conductive layer disposed between the conductive layer and the pixel isolation insulation layer.

3. The image sensor of claim 2, wherein the pixel isolation trench comprises a first portion passing through the semiconductor substrate and a second portion passing through the buried insulation layer, and the insulation liner is disposed on an inner wall of each of the first portion and the second portion of the pixel isolation trench,
wherein a first portion of the insulation liner disposed in the first portion of the pixel isolation trench contacts the barrier conductive layer, and
wherein a second portion of the insulation liner disposed in the second portion of the pixel isolation trench contacts the buried insulation layer.

4. The image sensor of claim 2, wherein an upper surface of the pixel isolation structure is disposed at a same level as an upper surface of the buried insulation layer.

5. The image sensor of claim 2, wherein the conductive layer comprises a reflective metal material.

6. The image sensor of claim 2, wherein the conductive layer comprises at least one of aluminum (Al), copper (Cu), silver (Ag), cobalt (Co), tungsten (W), platinum (Pt), gold (Au), chromium (Cr), titanium (Ti), nickel (Ni), molybdenum (Mo), iron (Fe), magnesium (Mg), iridium (Ir), palladium (Pd), or ruthenium (Ru).

7. The image sensor of claim 2, further comprising:
a device isolation layer disposed in a device isolation trench, the device isolation layer defining an active region of the semiconductor substrate; and
an etch stop layer disposed between the first surface of the semiconductor substrate and the buried insulation layer, between the transmission gate and the buried insulation layer, and between an upper surface of the device isolation layer and the buried insulation layer,
wherein a sidewall of the pixel isolation structure contacts the device isolation layer and the etch stop layer.

8. The image sensor of claim 7, wherein an upper surface of the conductive layer is disposed at a level which is lower than a bottom surface of the device isolation layer.

9. The image sensor of claim 7, wherein an upper surface of the conductive layer is disposed at a level which is higher than a bottom surface of the device isolation layer and lower than the upper surface of the device isolation layer.

10. The image sensor of claim 7, wherein an upper surface of the conductive layer is disposed at a level which is higher than the upper surface of the device isolation layer.

11. The image sensor of claim 2, wherein the pixel isolation insulation layer comprises a void therein.

12. The image sensor of claim 1, wherein the semiconductor substrate has a first height in a vertical direction, and
wherein the pixel isolation structure has a second height which is higher than the first height in the vertical direction.

13. An image sensor comprising:
a semiconductor substrate including a first surface, and a second surface opposite to the first surface, the semiconductor substrate further including a photoelectric conversion region;
a transmission gate disposed on the first surface of the semiconductor substrate;
an etch stop layer disposed on the first surface of the semiconductor substrate to cover the transmission gate; and
a pixel isolation structure disposed in a pixel isolation trench, the pixel isolation trench extending toward the second surface of the semiconductor substrate from the first surface of the semiconductor substrate, the pixel isolation structure including a conductive layer including a reflective metal material,
wherein an end portion of the etch stop layer is disposed on the conductive layer, and the pixel isolation structure and the etch stop layer do not vertically overlap each other.

14. The image sensor of claim 13, wherein the pixel isolation structure further comprises:
a barrier conductive layer disposed on a sidewall of the conductive layer;
a pixel isolation insulation layer disposed in a second portion of the pixel isolation trench, the second portion being disposed at a level which is higher than a first portion of the pixel isolation trench; and
an insulation liner disposed between the semiconductor substrate and the barrier conductive layer, the insulation liner extending on an inner wall of the pixel isolation trench in a vertical direction perpendicular to the first surface of the semiconductor substrate.

15. The image sensor of claim 14, further comprising:
a buried insulation layer disposed on the etch stop layer to cover the transmission gate; and
a device isolation layer disposed in a device isolation trench, the device isolation layer defining an active region of the semiconductor substrate,
wherein the pixel isolation trench passes through the buried insulation layer and extends in the vertical direction.

16. The image sensor of claim 15, wherein the end portion of the etch stop layer is aligned with a sidewall of the device isolation layer, and
wherein the insulation liner contacts the sidewall of the device isolation layer and the end portion of the etch stop layer.

17. The image sensor of claim 16, wherein the insulation liner is disposed on an entire inner wall of the pixel isolation trench, and
wherein an upper surface of the conductive layer is disposed at a level which is lower than a bottom surface of the device isolation layer.

18. The image sensor of claim 13, wherein the conductive layer comprises at least one of aluminum (Al), copper (Cu), silver (Ag), cobalt (Co), tungsten (W), platinum (Pt), gold (Au), chromium (Cr), titanium (Ti), nickel (Ni), molybdenum (Mo), iron (Fe), magnesium (Mg), iridium (Ir), palladium (Pd), or ruthenium (Ru).

19. An image sensor comprising:
a semiconductor substrate including a first surface, and a second surface opposite to the first surface, the semiconductor substrate further including a photoelectric conversion region;
a transmission gate disposed on the first surface of the semiconductor substrate; and
a pixel isolation structure disposed in a pixel isolation trench, the pixel isolation trench extending up to the second surface of the semiconductor substrate from the first surface of the semiconductor substrate,
wherein the pixel isolation structure comprises:
a conductive layer disposed in the pixel isolation trench, the conductive layer extending in a vertical direction perpendicular to the first surface of the semiconductor substrate;
a barrier conductive layer disposed on a sidewall of the conductive layer, in the pixel isolation trench;
a pixel isolation insulation layer disposed on the conductive layer and the barrier conductive layer, in the pixel isolation trench; and
an insulation liner extending in the vertical direction on an inner wall of the pixel isolation trench, the insulation liner covering a sidewall of the pixel isolation insulation layer and a sidewall of the barrier conductive layer, and
wherein an upper surface of the pixel isolation insulation layer is disposed at a level which is higher than the first surface of the semiconductor substrate.

20. The image sensor of claim 19, further comprising:
a device isolation layer disposed in a device isolation trench, the device isolation layer defining an active region of the semiconductor substrate;
an etch stop layer disposed on the first surface of the semiconductor substrate and the device isolation layer to cover an upper surface of the transmission gate; and
a buried insulation layer disposed on an upper surface of the etch stop layer,
wherein the pixel isolation trench passes through the buried insulation layer and extends in the vertical direction, and an upper surface of the pixel isolation structure is disposed at a same level as an upper surface of the buried insulation layer.
